(19) United States
(12) Patent Application Publication
(10) Pub. No.: US 2025/0304841 A1
(43) Pub. Date: Oct. 2, 2025

(54) SYSTEM AND A METHOD FOR CHEMICAL MECHANICAL PLANARIZATION, AND A COMPOSITION KIT, A RINSE COMPOSITION, AND A PLANARIZATION METHOD USED IN THE SAME

(71) Applicant: Fujimi Incorporated, Kiyosu-shi (JP)

(72) Inventors: Shogo Onishi, Tualatin, OR (US); Tsutomu Yoshino, Kiyosu (JP); Takahito Nagano, Tongluo Township (TW)

(21) Appl. No.: 19/056,572

(22) Filed: Feb. 18, 2025

Related U.S. Application Data
(60) Provisional application No. 63/570,616, filed on Mar. 27, 2024.

(51) Int. Cl. C09K 3/14; H01L 21/02; H01L 21/306; H01L 21/67

(52) U.S. Cl. CPC C09K 3/1463; C09K 3/1409; H01L 21/02065; H01L 21/30625; H01L 21/67023; H01L 21/67092

(57) ABSTRACT

Systems and methods are provided for chemical planarization. The polishing composition for polishing the wafer includes an abrasive, a pH adjuster, and an oxidizer while the rinse composition for rinsing the wafer includes at least one polymer and a pH adjuster. A ratio of an oxidation-reduction potential of the rinse composition to an oxidation-reduction potential of the polishing composition is greater than 0 and less than 0.76.

### CROSS REFERENCE TO RELATED APPLICATION

The present application claims priority to U.S. Provisional Application No. 63/570,616, entitled “SYSTEM AND A METHOD FOR CHEMICAL MECHANICAL PLANARIZATION”, and filed on Mar. 27, 2024. The entire contents of the above-listed application are hereby incorporated by reference for all purposes.

### BACKGROUND OF THE INVENTION

### Field of the Invention

The present description relates generally to compositions and planarization methods for chemical mechanical planarization.

### Description of the Related Art

Chemical mechanical planarization (CMP) is a process used in fabrication of nano and microelectronics. As one example, CMP may be used after an additive patterning step such as material deposition to form a planar wafer surface in preparation for a subsequent manufacturing step. During CMP, a polishing object, such as a wafer, is rotated in concert with a polishing pad and a polishing composition is introduced therebetween. The polishing composition includes components to both chemically soften and physically degrade the material being removed. For example, the polishing composition may include an oxidizing agent selected to oxidize the material being removed and to work synergistically with the abrasives included in the polishing composition to mechanically degrade the material being removed. After polishing, a planar, defect free surface is desired. However, the polishing composition may leave behind abrasives, residues, and other contaminants that may cause defects resulting in degradation of a performance of the final device.

### SUMMARY OF THE INVENTION

Other attempts to address contamination caused by the polishing composition include adding a rinse step, wherein a rinse composition is introduced between the rotating polishing pad and wafer after polishing is finished. The rinse composition is conventionally water, or may include additional components. However, the inventors have recognized potential issues with such systems. For example, using water alone as a rinse composition may merely dilute contaminants and may not be as effective as a rinse composition including additional reagents configured to further interact with the contaminants, either physically or chemically. Additional reagents may further interact with both the contaminants and the polished wafer. If a balance between the polishing composition and the rinse composition is not present, the rinse composition may not effectively decrease a number of defects present on the wafer.

In one example, the issues described above may be at least partially addressed by a system for chemical mechanical planarization of a wafer, comprising a polishing composition for polishing the wafer comprising abrasive particles, a pH adjuster, and an oxidizer; and a rinse composition for rinsing the wafer comprising at least one polymer and a pH adjuster, wherein a ratio of an oxidation-reduction potential of the rinse composition to an oxidation-reduction potential of the polishing composition is greater than 0 and less than 0.76.

It should be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE DRAWINGS

FIG. 1 shows a flowchart of an example of a system for chemical mechanical planarization of a wafer comprising a polishing composition and a rinse composition, in which a ratio of an oxidation-reduction potential of the rinse composition (Vrinse) to an oxidation-reduction potential of the polishing composition (Vpolish) is balanced within a range.

FIG. 2 shows a diagram of a chemical mechanical planarization (CMP) system.

FIG. 3 shows a flowchart of an example of a method for CMP using a balanced polishing composition and rinse composition.

### DETAILED DESCRIPTION

Herein, the term “X to Y” is used in the sense that preceding and following numerical values (X and Y) are included as the lower limit and the upper limit, and means “X or greater and Y or less”. When there are a plurality of “X to Y”, for example, when it is described that “X1 to Y1, or X2 to Y2”, ranges using these numerical values as the upper limits, ranges using these numerical values as the lower limits, and ranges of combinations of these upper and lower limits are all disclosed (which can be a legal basis for amendment). Specifically, amendment to “X1 or grater”, amendment to “Y2 or less”, amendment to “X1 or less”, amendment to “Y2 or greater”, amendment to “X1 to X2”, amendment to “X1 to Y2” and the like should be all regarded to be legal. The term “X or greater” means X or greater than X, and hence encompasses the meaning of “over X”. Similarly, the term “Y or less” means Y or less than Y, and hence encompasses the meaning of “less than Y”. Besides, an operation and measurement of a physical property and the like are performed under conditions of room temperature (20 to 25° C.)/relative humidity of 40 to 50% RH unless otherwise stated. A concentration described herein may be a concentration at a point of use (POU), or a concentration before dilution to the concentration at a POU. A dilution ratio may be 2 to 10 times. It should be understood that all combinations of examples and descriptions disclosed herein are disclosed in the present application. In other words, it should be understood that these can be a basis of amendment. Besides, in description of a content or a concentration of each component, when two or more components are included, the content or the concentration may be a total content or concentration.

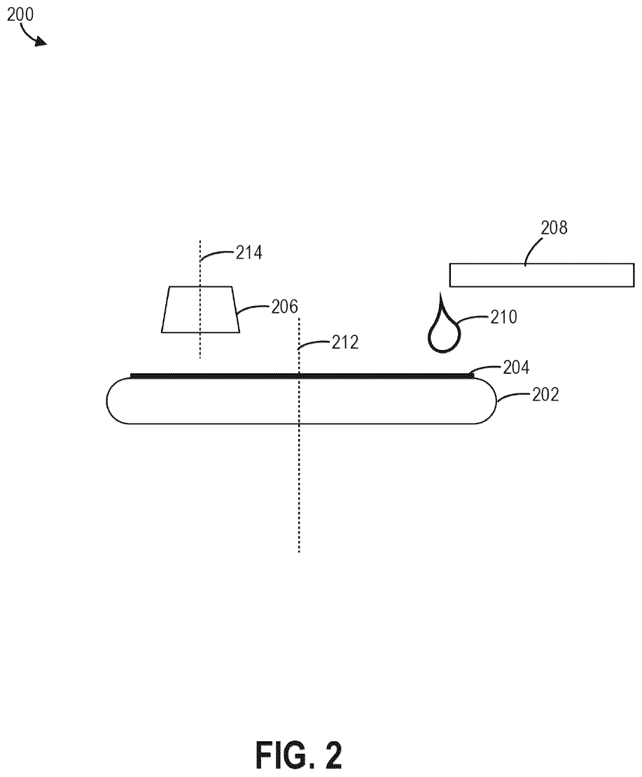

The following description relates to compositions and methods of preparing a polishing composition and a rinse composition for chemical mechanical planarization (CMP) and preparing a wafer using a CMP system. An example of a portion of a CMP system is shown in FIG. 2. CMP may be used to remove a layer of material from a polishing object, for example, during fabrication of a nano or microelectronic device, thereby forming a planar surface. Herein a polishing object may be a wafer, such as a semiconductor wafer used in manufacturing of electronics, although other polishing objects are also considered. The wafer may include a substrate and one or more layers of material may be deposited in around the substrate. In some examples CMP may remove a layer of the deposited material from the substrate.

In some examples, the removal of the layer may expose portions of the substrate or a different layer underneath the removed layer of material. In some examples the substrate may be a semiconductor or semiconductor oxide. The material of the layer being removed may vary depending on the device and the step of manufacturing. For example, the layer being removed may be organic (e.g., amorphous carbon, or an organic film containing elements other than carbon), a semiconductor (e.g., polycrystalline silicon), a ceramic (e.g., silicon nitride, or silicon dioxide formed from tetraethyl orthosilicate [TEOS]), or a metal (e.g., tungsten). Abrasive particles and an oxidizing agent of a polishing composition may be selected based on a chemical composition of the layer being removed. Generally, the polishing composition, regardless of a nature of the oxidizing agent or abrasive particles may leave behind contaminants on the wafer surface, demanding application of rinse composition using the CMP system to remove said contaminants and minimize a number of defects on the wafer surface. Herein, rinsing may refer to a process occurring after polishing, on the same or a different platen in the CMP system, using a polishing pad under the same or similar conditions to the polishing process while applying the rinsing composition to the surface to remove the polishing composition after polishing. After rinsing, the wafer may be cleaned. Herein cleaning refers to a process performed after polishing and rinsing which includes transferring the wafer to a cleaning system. The cleaning system is separate from the CMP system and may further clean the wafer, often in an aqueous media (e.g., via flow of water, and/or sonication).

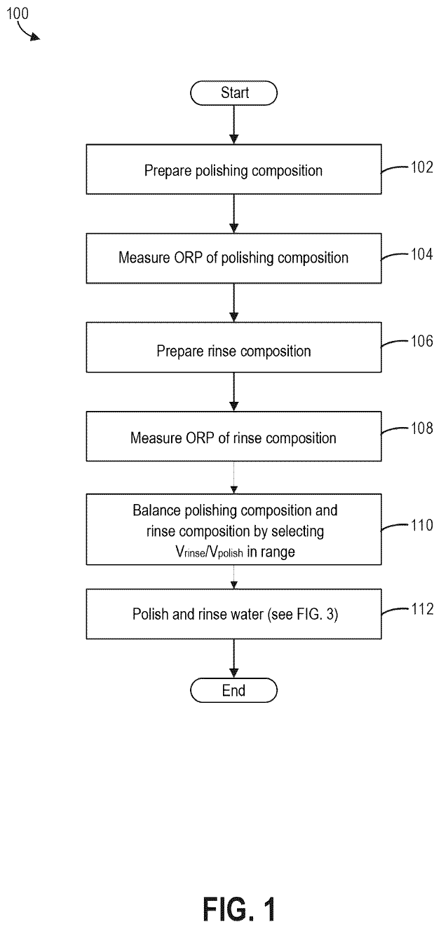

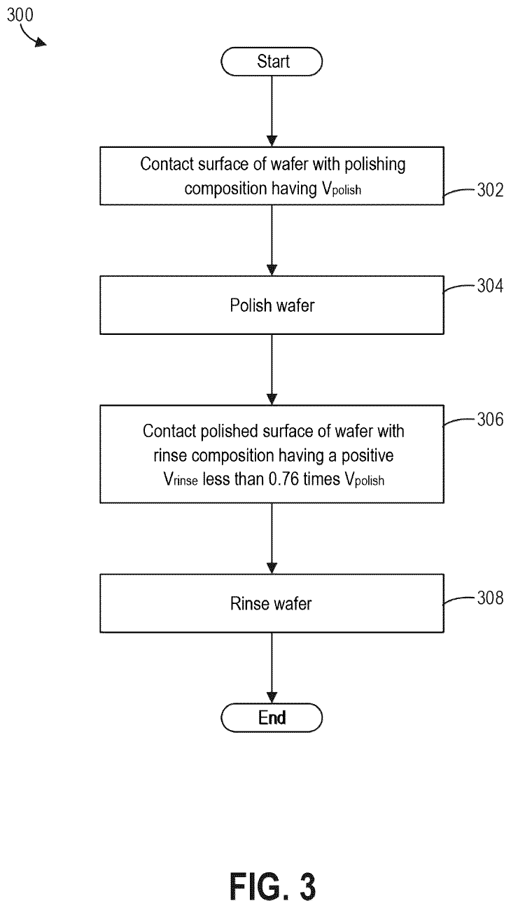

Conventionally, water alone may be used for a rinse step regardless of components included in the polishing composition. While water may be compatible with many different polishing compositions, water merely dilutes contaminants and does not actively clean a surface of the wafer. In some examples, additional components may be included in the rinse composition, but each component of the rinse composition may also interact with components of the polishing composition and selecting a rinse composition may demand undue experimentation. Inventors herein recognize that by balancing oxidation-reduction potential (ORP) of a polishing compositions and an ORP of a rinse composition, a combination of polishing composition and rinse composition that decrease a number of defects on a surface of the wafer may be selected. Flowcharts of method for preparing a balanced polishing composition and rinse composition and subsequently polishing and rinsing a polishing object are shown in FIGS. 1 and 3 respectively. In this way, a polishing composition may be selected for removing a layer and a corresponding rinse composition which balances the polishing composition may be prepared without undue experimentation.

Briefly, an example of a portion of a CMP system 200 is shown in FIG. 2. The portion of the CMP system 200 shows a platen 202 supporting a polishing pad 204. The platen 202 may be configured to rotate in a first direction about first rotational axis 212. A polishing pad 204 may be in face sharing contact with the platen and may be rotated by the platen. A wafer holder 206 may be configured to hold a wafer or other polishing object in an orientation to bring a layer to be removed/planarized in face sharing contact with polishing pad 204. Wafer holder 206 may be configured to rotate about axis 214, thereby also rotating the wafer. The platen 202 and wafer holder 206 may be configured to rotate in the same direction. Wafer holder 206 may be further configured to bring the polishing object in contact with polishing pad 204 with a controlled contact pressure. A supply system 208 may be configured to deliver composition 210 to a surface of polishing pad 204 at a controlled flow rate. In this way composition 210 may be distributed to an interface between the wafer and polishing pad 204. The CMP system may further comprise a polishing composition configured for polishing the wafer, including removing a layer of material from the wafer and a rinse composition for rinsing the wafer and configured to remove contaminants left behind by the polishing composition. The rinse composition and polishing composition may be balanced to have a ratio of ORP of the rinse composition to ORP of the polishing composition greater than zero and less than 0.76 (e.g., less than 0.65). Methods of preparing and using the rinse composition and polishing composition are described further below with respect to FIGS. 1 and 3.

Turning now to FIG. 1, an example of a method 100 for polishing and rinsing a wafer by balancing a polishing composition ORP and rinse composition ORP is shown. Method 100 may be performed manually, (e.g., by a technician) or in an automated or semi-automated fashion in a processing environment. Polishing and rinsing may be performed by a CMP system, such as the CMP system shown in FIG. 2 and described above.

At 102, method 100 includes preparing a polishing composition. In some examples the polishing composition may be a polishing slurry and may include abrasive particles that do not dissolve in the liquid carrier. As one example, the polishing composition may include abrasive particles, an oxidizer, a pH adjuster, water and optionally an additive. The abrasive particles may be particulates having a hardness greater than a hardness of the layer being removed.

The Vickers hardness (unit: GPa; HV 9.807 N) of the abrasive particles may be less than 11. Examples of abrasive particles having a Vickers hardness of less than 11 include SiO₂ (Vickers hardness: 9.7) and AlN (Vickers hardness: 10.4). The Vickers hardness of the abrasive particles is, for example, 7 or greater and less than 11. The Vickers hardness of the abrasive particles may be 11 or greater. Examples of abrasive particles having a Vickers hardness of 11 or greater include ZrO₂ (Vickers hardness: 11.8 to 13), Al₂O₃(Vickers hardness: 14.5 to 18), and silicon carbonate (Vickers hardness: 22.5 to 28). The Vickers hardness of the abrasive particles is, for example, 11 or greater and 20 or less, and preferably 11 or greater and 15 or less. The Vickers hardness may be calculated in accordance with JIS Z 2244:2009. In some examples, a ratio occupied by silica particles (colloidal silica particles) in the abrasive particles included in the polishing composition is 85 wt. % or greater, 90 wt. % or greater, 95 wt. % or greater, or 99 wt. % or greater, or a ratio occupied by zirconia particles in the abrasive particles included in the polishing composition is 85 wt. % or greater, 90 wt. % or greater, 95 wt. % or greater, or 99 wt. % or greater.

In some examples, a polishing composition comprising abrasive particles having a Vickers hardness of less than 11 is used for polishing at least one of TEOS, poly-Si, SiN, a-carbon, and W, suitably used for polishing at least one of TEOS, poly-Si, SiN, and W, and more suitably used for polishing at least one of TEOS, poly-Si, and SiN. In some examples, a polishing composition comprising abrasive particles having a Vickers hardness of 11 or greater is used for polishing at least one of TEOS, poly-Si, SiN, a-carbon, and W, suitably used for polishing at least one of TEOS, SiN, a-carbon, and W, and more suitably used for polishing at least one of TEOS, SiN, and W. More suitably, such a polishing composition is used for polishing at least one of TEOS, and SiN.

In some examples, a Mohs hardness of the abrasive particles is less than 9. In further examples, the Mohs hardness of the abrasive particles is greater than 7. In some examples, the abrasive particles may be of SiO₂ or ZrO₂, or the like. In further examples, SiO₂ may be surface treated to have a positive or negative surface potential, as determined by a measurement of zeta potential of the abrasive particles. A weight percent of the abrasive particles in the slurry may be selected. As one example, the weight percent may be in a range of greater than 0% and less than 4%. As a further example, the weight percent may be in a range of 0.5% to 3%. As a further example the weight percent of abrasive particles in the slurry may be 1.5%. As a further example, the weight percent may be in a range of 0.5% to 2%. As a further example, the weight percent may be in a range of 0.5% to 1.5%. As a further example, the weight percent of the abrasive particles in the slurry may be 0.1 wt. % or greater, 0.3 wt. % or greater, 0.5 wt. % or greater, 0.7 wt. % or greater, 0.9 wt. % or greater, 1.1 wt. % or greater, or 1.3 wt. % or greater. As a further example, the weight percent of the abrasive particles in the slurry may be 10 wt. % or less, 8 wt. % or less, 6 wt. % or less, 4 wt. % or less, or 2 wt. % or less. The abrasive particles may be polishing nanoparticles. As one example, a mean particle diameter of the polishing nanoparticles may be more than 10 nm. As one example, a mean particle diameter of the polishing nanoparticles may be more than 20 nm. As one example, a mean particle diameter of the polishing nanoparticles may be more than 30 nm. As one example, a mean particle diameter of the polishing nanoparticles may be more than 50 nm. As one example, a mean particle diameter of the polishing nanoparticles may be less than 200 nm. As one example, a mean particle diameter of the polishing nanoparticles may be less than 150 nm. As one example, a mean particle diameter of the polishing nanoparticles may be less than 120 nm. As one example, a mean particle diameter of the polishing nanoparticles may be less than 100 nm. As one example, a mean particle diameter of the polishing nanoparticles may be in the range of 10 nm to 250 nm. As one example, a mean particle diameter of the polishing nanoparticles may be in the range of 10 nm to 200 nm. As one example, a mean particle diameter of the polishing nanoparticles may be in the range of 15 nm to 150 nm. As one example, a mean particle diameter of the polishing nanoparticles may be in the range of 20 nm to 120 nm. As one example, a mean particle diameter of the polishing nanoparticles may be in the range of 30 nm to 100 nm. As one example, a mean particle diameter of the polishing nanoparticles may be in the range of 40 nm to 90 nm. As one example, a mean particle diameter of the polishing nanoparticles may be in the range of 50 nm to 80 nm. As one example, a mean particle diameter of the polishing nanoparticles may be about 70 nm. Herein, the term “about X (X being a numerical value)” may mean that ±10% or ±5% of X is further included, and for example, as for ±10%, the term means X×0.9 to X×1.1. Besides, “about X” may be X itself. A mean particle diameter may be measured by employing any appropriate method known in this technical field (e.g., by a light scattering method using, for example, Zetasizer® Nano ZS manufactured by Malvern Panalytical® Ltd.)

The oxidizer may be selected based on a chemical composition of the layer being removed by CMP. For example, the oxidizer may be selected to chemically react with the layer being removed to soften the layer. The oxidizer may be a substance having an oxidation-reduction potential sufficient for exhibiting an effect of oxidizing the surface of the layer. The oxidizer may be, for example, a substance having an oxidation-reduction potential higher than the oxidation-reduction potential of a material included in the layer at a pH at which polishing and rinsing are conducted. Here, the pH at which polishing is conducted is usually the same as the pH of the polishing composition. The pH at which rinsing is conducted is usually the same as the pH of the rinse composition. As one example, the oxidizer may be a permanganate salt, nitrate salt, a peroxide, an oxidizing acid or the like. As a further example the oxidizer may be one or more of hydrogen peroxide, potassium permanganate, ceric ammonium nitrate, periodic acid, ferric nitrate or aluminum nitrate. The oxidizer may be included in a wt. % in a range of greater than 0.0% up to 10.0%, in a range of 0.01% up to 5%, in a range of 0.05% up to 3%, or in a range of 0.1% up to 2%. As a further example, the oxidizer may be included in a wt. % in a range of 0.30% up to 1.0%. As one example, the oxidizer may be included in the polishing composition in a wt. % of 0.001% or greater, 0.005% or greater, 0.01% or greater, 0.015% or greater, 0.02% or greater, 0.025% or greater, 0.03% or greater, 0.035% or greater, 0.04% or greater, 0.045% or greater, 0.05% or greater, 0.07% or greater, 0.1% or greater, 0.5% or greater, or 0.7% or greater. As one example, the oxidizer may be included in the polishing composition in a wt. % of 5% or less, 4% or less, 3% or less, 2% or less, 1% or less, 0.8% or less, 0.6% or less, 0.4% or less, 0.2% or less, 0.1% or less, 0.08% or less, 0.06% or less, or 0.04% or less.

A pH adjuster may be an acid included to adjust a pH of the polishing composition to a desired level. As one example the pH may be adjusted to be in a range of 2.0 to 10.0. As a further example, the pH of the polishing composition may be adjusted to be acidic, having a pH of less than 7.0. Alternatively, the pH may be adjusted to 6.0 or less, or may be adjusted to 5.0 or less. As a further example, the pH of the polishing solution may be adjusted to be in a range of 2.0 to 4.5. As a further example, the pH of the polishing composition is 1.2 or greater, 1.4 or greater, 1.6 or greater, 1.8 or greater, 2.0 or greater, 2.2 or greater, 2.4 or greater, 2.6 or greater, 2.8 or greater, 3.0 or greater, 3.2 or greater, 3.4 or greater, 3.6 or greater, 3.8 or greater, or 4.0 or greater. As a further example, the pH of the polishing composition is 4.3 or less, 4.1 or less, 3.9 or less, 3.7 or less, 3.5 or less, 3.3 or less, 3.1 or less, 2.9 or less, 2.7 or less, 2.5 or less, or 2.3 or less. The pH adjuster may be an acid or base, depending on if adjustment is to increase or decrease pH. As one example the pH adjuster may be an inorganic acid such as sulfuric acid, nitric acid, boric acid, phosphoric acid, or the like. As a further example, the pH adjuster may be an organic acid such as carboxylic acids, organic sulfuric acids, or the like. As an additional example, the pH adjuster may be a base, including hydroxides of an alkali metal such as potassium hydroxide. As a further example, the pH adjuster may be an amine or a quaternary ammonium salt. In some examples, the pH adjuster may a combination two or more of the above listed acids and/or bases. Herein, the pH of a composition may be measured by any appropriate method known in this technical field (for example, by using ThermoFisher Scientific, Orion™ VERSA STAR PRO™ pH/ISE/Conductivity/Dissolved Oxygen Multiparameter Benchtop Meter).

In some examples an additive may be included in the polishing composition. In some examples, the additive includes antiseptic agents, antifungal agents, biocides (e.g., isothiazolinones such as methylisothiazolinone (“MIT”), benzisothiazolinone (“BIT”), 2-methyl-4-isothiazolin-3-one, etc.), dispersants (additives that improve the redispersibility of abrasive grains that have once settled), electrical conductivity adjusting agents (additives that adjust the electric conductivity of the polishing composition), abrasive grains other than the abrasive grains mentioned above, chelating agents, reducing agents, polymers, surfactant and dissolved gases.

The polishing composition may be prepared by mixing the components of the polishing composition with water to achieve the desired wt. % of each. In examples, the oxidizer may be provided as a concentrated aqueous solution and may be mixed with water and the remaining components to achieve a desired wt. % of each. A demanded amount of pH adjuster may then be added to reach a desired pH. The composition may be mixed until water soluble components are dissolved and abrasive particles are homogeneously suspended.

At 104, method 100 includes measuring an ORP of the of polishing composition (Vₚₒₗᵢₛₕ). Measuring the ORP of the polishing composition may include measuring using an ORP sensor including an inert electrode configured to measure a ORP of a composition against a reference electrode (e.g., a silver/silver chloride). Measuring the ORP of the polishing composition may include immersing the ORP sensor in the polishing composition while simultaneously mixing the polishing composition at a rate to ensure even distribution of the slurry. For example, the slurry may be stirred at 200 rpm. The polishing composition be at room temperature (e.g., 25° C.°) while measuring the ORP. Further, measuring the ORP of the polishing solution may include immersing the ORP sensor for a threshold amount of time. The threshold amount of time may be long enough for a voltage measured by the ORP sensor to stabilize. For example, the threshold amount of time may be one minute.

At 106, method 100 includes preparing a rinse composition. The rinse composition may include at least one polymer, a pH adjuster, water, and optionally an oxidizer and/or an additive. In some examples, the rinse composition may or may not include an oxidizer. Herein, the term “may include” or the like simultaneously means “may not include” or the like. As one example, an oxidizer may be included in the rinse composition in wt. % of 0.001% or greater, 0.005% or greater, 0.01% or greater, 0.015% or greater, 0.02% or greater, 0.025% or greater, 0.03% or greater, 0.035% or greater, 0.04% or greater, 0.045% or greater, 0.05% or greater, 0.07% or greater, 0.1% or greater, 0.5% or greater, or 0.7% or greater. As one example, the oxidizer may be included in the rinse composition in wt. % of 5% or less, 4% or less, 3% or less, 2% or less, 1% or less, 0.8% or less, 0.6% or less, 0.4% or less, 0.2% or less, 0.1% or less, 0.08% or less, 0.06% or less, or 0.04% or less. In some examples, the concentration (wt. %) of the oxidizer in the polishing composition is higher than the concentration (wt. %) of the oxidizer in the rinse composition. In these examples, the Vickers hardness of the abrasive particles included in the polishing composition is preferably less than 11. In some examples, a ratio of the concentration (wt. %) of the oxidizer in the polishing composition to the concentration (wt. %) of the oxidizer in the rinse composition is 2 or greater, 5 or greater, or 8 or greater. The upper limit is, for example, 15 or less. In some examples, the concentration (wt. %) of the oxidizer in the polishing composition is lower than the concentration (wt. %) of the oxidizer in the rinse composition. In some examples, a ratio of the concentration (wt. %) of the oxidizer in the rinse composition to the concentration (wt. %) of the oxidizer in the polishing composition is 2 or greater, 5 or greater, 8 or greater, 10 or greater, or 13 or greater. The upper limit is, for example, 20 or less. In some examples, the components of the rinse composition may be soluble in water and the rinse composition may be a rinse solution. As one example, the polymer may be a water soluble polymer having a molecular weight of at least 100 g/mol. The at least one polymer may include an atom having a higher electronegativity than carbon, for example, an oxygen, sulfur, nitrogen, fluorine, or chlorine. As one example, the at least one polymer may include a hydroxyl group, sulfuric oxide, or an amino group. In some examples, the rinse composition includes an anionic polymer as the polymer. In some examples, the anionic polymer includes a sulfonic acid group. In some examples, the anionic polymer includes at least one of polystyrenesulfonic acid and a copolymer of styrene sulfonic acid and polyvinylalcohol. In some examples, the rinse composition includes a nonionic polymer as the polymer. In some examples, the nonionic polymer includes polyvinylalcohol. In some examples, a degree of saponification of the polyvinylalcohol is not 100%. Since the degree of saponification of the polyvinylalcohol is not 100%, an effect of improving solubility is obtained. As a result, working time necessary for dissolving the polymer is decreased. Besides, an effect of decreasing the number of coarse particles having a particle diameter of 0.2 μm or greater is obtained. Coarse particles are measured, for example, by the following method.

### (Measuring Apparatus)

Liquid-borne Particle Counters (KS-41B: manufactured by RION Co., Ltd.)

### (Conditions)

Data correction time: 60 sec
Sample dilution target: 2000 count/mL
Sample flow rate: 10 mL/min.

The number of coarse particles measured under the above-described conditions is preferably 20,000 or less, and more preferably 10,000 or less per cm³. In some examples, the nonionic polymer includes polyvinylpyrrolidone (PVP). For example, the at least one polymer may be polystyrenesulfonic acid (PSSA), polyvinylalcohol (PVA), anionic PVA (e.g., PVA with sulfonic acid group in side chain), cationic PVA (e.g., PVA with amino group in side chain), polyacrylic acid (PA), poly(N-vinylacetamide) (PNVA), polyvinylpyrrolidone (PVP), Hydroxyethyl cellulose (HEC). The at least one polymer may further include copolymers of the above listed polymers with other substances. In some examples a degree of saponification of the at least one polymer is not 100%. In some examples, the at least one polymer may include a first polymer and a second polymer. In further examples, a wt. % of the first polymer in the rinse composition may be less than a wt. % of the second polymer. In some examples, the wt. % of the first polymer may be half of a wt. % of the second polymer. In some examples the first polymer may be included in wt. % in a range of 0 to 0.5% and the second polymer may be included in range of greater than 0% up to 0.1%. In some examples, the polymer has a molecular weight of at least about 1000 g/mol, at least about 5000 g/mol, at least about 10000 g/mol, at least about 15000 g/mol. In some examples, the polymer has a molecular weight of at most about 100000 g/mol, at most about 50000 g/mol, at most about 30000 g/mol. In some examples, a ratio of the concentration (wt. %) of the nonionic polymer to the concentration (wt. %) of the anionic polymer in the rinse composition is over 1, 3 or greater, 5 or greater, 8 or greater, 10 or greater, or 15 or greater. In some examples, a ratio of the concentration (wt. %) of the nonionic polymer to the concentration (wt. %) of the anionic polymer in the polishing composition is 50 or less, 40 or less, or 30 or less. In some examples, a ratio of the concentration (wt. %) of the anionic PVA to the concentration (wt. %) of the anionic polymer in the rinse composition is over 1, 3 or greater, 5 or greater, 10 or greater, or 15 or greater. In some examples, a ratio of the concentration (wt. %) of the anionic PVA to the concentration (wt. %) of the anionic polymer in the rinse composition is 50 or less, 40 or less, or 30 or less.

In some examples, a weight average molecular weight of the polymer disclosed herein may be 1,000 to 100,000, 2,000 to 80,000, 3,000 to 60,000, 4,000 to 40,000, 5,000 to 30,000, 6,000 to 20,000, or 7,000 to 15,000. As a method for measuring the weight average molecular weight, the measurement is conducted, for example, by gel permeation chromatography (using Nexera™ GPC system, manufactured by Shimadzu Corporation).

In an exemplary embodiment, the first polymer may be PSSA and the second polymer may be PVA or anionic PVA. In an exemplary embodiment, the first polymer may be PSSA and the second polymer may be polyvinylpyrrolidone (PVP).

In some examples, the rinse composition may include an oxidizer. In some examples, the oxidizer may be selected based on an oxidizer of the polishing solution. In some examples, the rinse composition may not include an oxidizer. In some examples, the oxidizer may be hydrogen peroxide. The oxidizer may be included in a range of greater than zero wt. % to 0.1 wt. %. Additionally, the oxidizer of the rinse composition may be different than the oxidizer of the polishing composition. Further the oxidizer of the rinse composition may be a weaker oxidizer than the oxidizer of the polishing composition.

In some examples, the rinse composition may include an additive. For example, the additive may be carboxylic acid chelating agent, for example, ethylene diamine tetra acetic acid (EDTA), diethylene triamine penta acetic acid (DTPA), triethlyene tetramine penta acetic acid (TTHA), hydroxyethyl imino di acetic acid (HIDA), dihydroxyethyl glycine (DHEG), dicarboxymethyl glutamic acid (CMGA), (S,S)-ethylene diamine disuccinic acid (EDDS). For example, the additive may be phosphonic acid chelating agent, for example, nitrilotris (methylene phosphonic acid) (NTMP), phosphonobutane tricarboxylic acid (PBTC), ethylene diamine tetra(methylene phosphonic acid) (EDTMP), diethylenetriaminepenta(methylenephosophonic acid) (DTPMP). In some examples, the additive may be included in the rinse composition in wt. % in the range of 0.0001% or greater and 8.0% or less, 0.0003% or greater and 6.0% or less, 0.0005% or greater and 4.0% or less, 0.0007% or greater and 2.0% or less, 0.001% or greater and 1.0% or less, 0.003% or greater and 0.5% or less, 0.005% or greater and 0.1% or less, or 0.007% or greater and 0.05% or less.

A pH adjuster may be added to the rinse composition during preparation to adjust the pH to a desired pH. For example, the pH adjuster may be the same as the pH adjuster of the polishing composition. In some examples the pH adjuster of the rinse composition may be different than the pH adjuster of the polishing composition. In some examples, a pH adjuster of the rinse composition may be nitric acid, sulfuric acid, phosphoric acid, maleic acid, malonic acid, hydroxyisobutyric acid, and hydroxyethyl diene diphosphoric acid (HEDP). A pH of the rinse composition may be adjusted to be an acidic pH or a basic pH. In some examples, the pH may be adjusted to 7.0 or less, 6.0 or less, 5.0 or less, or 4.0 or less. In some examples, the pH may be adjusted to 1.0 or greater, 1.5 or greater, or 2.0 or greater. In some examples, the pH may be adjusted in a range of 1.5-10. In further examples, the pH of the rinse composition may be adjusted to be in a range of 1.5 to 4.5. As a further example, the pH of the rinse composition is 1.2 or greater, 1.4 or greater, 1.6 or greater, 1.8 or greater, 2.0 or greater, 2.2 or greater, 2.4 or greater, 2.6 or greater, 2.8 or greater, 3.0 or greater, 3.2 or greater, 3.4 or greater, 3.6 or greater, 3.8 or greater, or 4.0 or greater. As a further example, the pH of the rinse composition is 4.3 or less, 4.1 or less, 3.9 or less, 3.7 or less, 3.5 or less, 3.3 or less, 3.1 or less, 2.9 or less, 2.7 or less, 2.5 or less, or 2.3 or less. In some examples, the pH of the polishing composition and the pH of the rinse composition to be used in combination may be the same or different, and the pH of the polishing composition may be higher or lower than the pH of the rinse composition. When the pH of the polishing composition and the pH of the rinse composition are different, a difference therebetween is 3.0 or less, 2.5 or less, 2.0 or less, 1.5 or less, 1.0 or less, 0.8 or less, 0.6 or less, or 0.4 or less.

The rinse composition may be prepared in a manner similar to the polishing composition. Components of the rinse composition may be mixed in amounts to reach a desired weight % of each. A pH adjuster may be added last in amount demanded to adjust pH to a desired value. The components may be stirred until completely dissolved. In some examples, the rinse composition does not substantially include abrasive particles. The phrase “not substantially include abrasive particles” encompasses, in addition to a case in which the rinse composition does not include abrasive particles at all (below detection limit), a case in which abrasive particles are included in an amount of 0.001 wt. % or less.

At 108, method 100 includes measuring an ORP of the rinse composition (Vᵣᵢₙₛₑ). Measuring of the ORP of the rinse composition may include steps similar to measuring ORP of the polishing composition. Components of the rinse composition may be mixed in a mixing vessel until fully dissolved. An ORP sensor may be submersed in the rinse composition while simultaneously stirring the rinse composition. The rinse composition may be at room temperature when ORP is measured. The voltage read by the ORP sensor may be allowed to stabilize for the threshold time and a value for ORP determined from the ORP sensor.

It is shown that, at 104 and 108, the method includes the measuring ORPs of the polishing composition and the rinse composition respectively, but when those skilled in the art precedently know, from experience, that the ratio of the oxidation-reduction potential of the rinse composition to the oxidation-reduction potential of the polishing composition is greater than 0 and less than 0.76, the method need not include 104 and 108.

At 110, method 100 includes balancing a polishing composition and a rinse composition by selecting a ratio of Vᵣᵢₙₛₑ/Vₚₒₗᵢₛₕ within a range. As one example, Vₚₒₗᵢₛₕ is greater than Vᵣᵢₙₛₑ and the ratio is less than one. Preferably, Vᵣᵢₙₑ is greater than zero. In one example, the range of Vᵣᵢₙₛₑ/Vₚₒₗᵢₛₕ is greater than zero and less than 0.76. In a further example the range of Vᵣᵢₙₛₑ/Vₚₒₗᵢₛₕ is greater than 0.20 up to 0.60. In a further example, the range of Vᵣᵢₙₛₑ/Vₚₒₗᵢₛₕ is greater than 0.40 up to 0.55. In some examples, selecting the polishing composition may include selecting the polishing composition based on the layer being removed during CMP. Further, selecting the rinse composition may include selecting the rinse composition having a measured ORP resulting in a Vᵣᵢₙₛₑ/Vₚₒₗᵢₛₕ within the range. In one example, Vᵣᵢₙₛₑ/Vₚₒₗᵢₛₕ is 0.05 or greater, 0.07 or greater, 0.09 or greater, 0.11 or greater, 0.13 or greater, 0.15 or greater, 0.17 or greater, 0.19 or greater, 0.21 or greater, 0.23 or greater, 0.25 or greater, 0.27 or greater, 0.29 or greater, 0.31 or greater, 0.33 or greater, 0.35 or greater, 0.37 or greater, 0.39 or greater, 0.41 or greater, 0.43 or greater, 0.45 or greater, 0.47 or greater, 0.49 or greater, or 0.51 or greater. In one example, Vᵣᵢₙₛₑ/Vₚₒₗᵢₛₕ is 0.76 or less, 0.74 or less, 0.72 or less, 0.70 or less, 0.68 or less, 0.66 or less, 0.64 or less, 0.62 or less, 0.60 or less, 0.58 or less, 0.56 or less, 0.54 or less, 0.52 or less, 0.50 or less, 0.48 or less, 0.46 or less, 0.44 or less, 0.42 or less, 0.40 or less, 0.38 or less, 0.36 or less, 0.34 or less, 0.32 or less, 0.30 or less, 0.28 or less, or 0.26 or less.

Balancing the polishing composition and rinse composition may result in decreasing an amount of defects on a wafer surface caused by particles, organic residues, and the like. Further, balancing may result in making the defect causing material (e.g., particles, residues, etc.) hydrophilic and more readily dissolved when exposed to aqueous environments both during rinsing and cleaning. For example, the range of Vᵣᵢₙₛₑ/Vₚₒₗᵢₛₕ greater than zero and Vᵣᵢₙₛₑ greater than zero results in an oxidizing environment, the oxidation making the defect causing material more hydrophilic. However, over oxidizing the defect causing material may cause the defect causing material to become hydrophobic and therefore more difficult to remove in aqueous environments during rinsing and cleaning. Maintaining Vᵣᵢₙₛₑ/Vₚₒₗᵢₛₕ less than 0.76 may prevent the defect causing material from over oxidizing.

Method 100 proceeds to 112 and includes polishing the wafer using the polishing composition and rinsing the wafer using the rinse composition. In some examples, selected polishing composition and selected rinse composition may be included in a kit for use with a chemical mechanical planarization system. In some examples, the kit may include a polishing composition and a rinse composition, each including components as listed above. The kit may include the polishing and corresponding rinse compositions in a concentrated form, including less water than demanded for use during polishing/rinsing. In examples where the polishing or rinse compositions include a volatile oxidizing agent such as hydrogen peroxide, the oxidizing agent of the polishing and/or rinse composition may be included in the kit, physically separate from the remaining components of the composition may be added to the polishing and/or rinse composition directly before use for polishing or rinsing. Additionally or alternatively the oxidizing agent of the polishing and/or rinse composition may be non-volatile, such as potassium permanganate, and may be physically included in the polishing and/or rinse composition as provided. A user of the kit may dilute the polishing and rinse compositions to reach desired concentrations of components by adding a volume of pure water before polishing and rinsing the wafer via CMP. The user may further add the volatile oxidizing agent to the polishing and/or rinse compositions directly before using.

Polishing the wafer may include applying the polishing composition to the wafer removing a layer of wafer by chemical mechanical planarization. Rinsing the wafer may include applying the rinse composition to the wafer and rinsing using the CMP system to remove defect causing contaminants left behind by polishing. Rinsing may be performed by introducing the rinse composition to the chemical mechanical planarization system (e.g., via supply system 208 of FIG. 2) and replacing the polishing composition with the rinse composition. A rinse composition that is balanced with the polishing composition may effectively remove defect causing contaminants from the surface. Method 100 ends.

The methods of polishing and rinsing according to an embodiment are described further in a flowchart of a method 300 shown in FIG. 3. Method 300 may be performed using a CMP system including the polishing and rinse compositions as shown in FIG. 2 and described above. The method 300 may be performed after receiving a polishing composition and rinse composition prepared as described above with respect to method 100 of FIG. 1. Further, method 300 may be performed after preparing the polishing and rinse compositions using a kit, as described above.

At 302, method 300 includes contacting a surface of the wafer with a polishing composition having an oxidation-reduction potential (Vₚₒₗᵢₛₕ). The surface of the polishing object may contact the polishing composition on a surface of a polishing pad of the CMP system, while each are rotated as described above. The Vₚₒₗᵢₛₕ may be such that a desired chemical reaction occurs between the polishing composition and the layer being removed from the wafer. Further Vₚₒₗᵢₛₕ may be greater than zero. Additionally, contacting the surface of the wafer with polishing composition may leave behind contaminants on the polished surface.

At 304, method 300 includes polishing the wafer using the CMP system. Polishing the wafer may include rotating a platen of the CMP system at a set rpm and rotating the wafer at a set rpm and contacting the wafer with the polishing pad positioned on the platen. A polishing time may be selected based on a thickness of the layer being removed from the wafer.

At 306, method 300 includes contacting a polished surface of the wafer with a rinse composition having a positive oxidation-reduction potential (Vᵣᵢₙₛₑ) at least 1.5 less than Vₚₒₗᵢₛₕ (e.g., 0<Vᵣᵢₙₛₑ Vₚₒₗᵢₛₕ/1.5). In this way, the ratio of Vᵣᵢₙₛₑ/Vₚₒₗᵢₛₕ is within the range described above with respect to method 100. As one example, the range of Vᵣᵢₙₛₑ/Vₚₒₗᵢₛₕ is greater than zero and less than 0.76.

At 308, method 300 includes rinsing the wafer. Rinsing the wafer may include contacting the polished surface of the wafer with the rinse composition on a surface of a polishing pad of the CMP system, while each are rotated as described above. The rinse composition having a positive Vᵣᵢₙₛₑ at least 1.5 times less than Vₚₒₗᵢₛₕ which balances the rinse composition with the polishing composition. In some examples, the rinse time may be less than polishing time. In this way, a number of defects left behind after contacting the cleaned and polished surface of the polishing object with the rinse composition is minimized.

In some examples, when the Vickers hardness of the abrasive particles is less than 11 (for example, SiO₂), Vᵣᵢₙₛₑ/Vₚₒₗᵢₛₕ is over 0, 0.1 or greater, 0.15 or greater, 0.2 or greater, 0.25 or greater, 1.0 or less, 0.9 or less, 0.8 or less, less than 0.76, 0.7 or less, 0.6 or less, less than 0.53, 0.5 or less, less than 0.46, 0.4 or less, less than 0.38, or 0.3 or less.

In some examples, when the Vickers hardness of the abrasive particles is 11 or greater (for example, ZrO₂), Vᵣᵢₙₛₑ/Vₚₒₗᵢₛₕ is over 0, 0.1 or greater, 0.14 or greater, over 0.14, 0.15 or greater, over 0.15, 0.2 or greater, 0.3 or greater, 0.4 or greater, 0.75 or less (essential), 0.7 or less, 0.6 or less, or 0.55 or less.

The present invention also encompasses the following aspects and embodiments:

1. A system for chemical mechanical planarization of a wafer, comprising a polishing composition for polishing the wafer comprising abrasive particles, a pH adjuster, and an oxidizer; and a rinse composition, to be used in a rinse step performed after a polishing step, for rinsing the wafer comprising at least one anionic polymer and a pH adjuster, wherein a ratio of an oxidation-reduction potential of the rinse composition to an oxidation-reduction potential of the polishing composition is greater than 0 and less than 0.76.

2. The system of 1., wherein the ratio of the oxidation-reduction potential of the rinse composition to the oxidation-reduction potential of the polishing composition is less than 0.65.

3. The system of 1, or 2., wherein the anionic polymer comprises a sulfonic acid group.

4. The system of 3., wherein the anionic polymer comprises at least one of polystyrenesulfonic acid and a copolymer of styrene sulfonic acid and polyvinylalcohol.

5. The system of any one of 1. to 3., wherein the rinse composition comprises a nonionic polymer.

6. The system of 5., wherein the nonionic polymer comprises polyvinylalcohol, and wherein a degree of saponification of the polyvinylalcohol is not 100%.

7. The system of any one of 1. to 6., wherein a Vickers hardness of the abrasive particles is less than 11.

8. The system of any one of 1. to 6., wherein a Vickers hardness of the abrasive particles is 11 or greater.

9. The system of 7., wherein the abrasive particles are SiO₂.

10. The system of 8., wherein the abrasive particles are ZrO₂.

11. The system of any one of 1. to 10., wherein when a Vickers hardness of the abrasive particles is less than 11, the ratio of the oxidation-reduction potential of the rinse composition to the oxidation-reduction potential of the polishing composition is greater than 0 and less than 0.38.

12. The system of any one of 1. to 11., wherein when a Vickers hardness of the abrasive particles is 11 or greater, the ratio of the oxidation-reduction potential of the rinse composition to the oxidation-reduction potential of the polishing composition is greater than 0.14.

13. The system of any one of 1. to 12., wherein the ratio of the oxidation-reduction potential of the rinse composition to the oxidation-reduction potential of the polishing composition is greater than 0.15.

14. The system of any one of 1. to 13., wherein when a Vickers hardness of the abrasive particles is 11 or greater, the polishing composition comprises potassium permanganate.

15. A kit of a composition for chemical mechanical planarization of a wafer, comprising a polishing composition for polishing the wafer comprising abrasive particles, a pH adjuster, and an oxidizer; and a rinse composition, to be used in a rinse step performed after a polishing step, for rinsing the wafer comprising at least one anionic polymer and a pH adjuster, wherein a ratio of an oxidation-reduction potential of the rinse composition to an oxidation-reduction potential of the polishing composition is greater than 0 and less than 0.76.

16. A rinse composition to be used in a rinse step performed after a polishing step using a polishing composition for polishing a wafer comprising abrasive particles, a pH adjuster, and an oxidizer, wherein a ratio of an oxidation-reduction potential of the rinse composition to an oxidation-reduction potential of the polishing composition is greater than 0 and less than 0.76.

17. A method for chemical mechanical planarization of a wafer, comprising a polishing step of contacting a surface of the wafer with a polishing composition for polishing the wafer comprising abrasive particles, a pH adjuster, and an oxidizer; and a rinse step of contacting the polished surface of the wafer after the polishing step with a rinse composition for rinsing the wafer comprising at least one anionic polymer and a pH adjuster, wherein a ratio of an oxidation-reduction potential of the rinse composition to an oxidation-reduction potential of the polishing composition is greater than 0 and less than 0.76.

18. The method of 16. or 17., wherein the surface of the wafer includes a layer formed of at least one of: TEOS, polycrystalline silicon, silicon nitride, amorphous carbon, or tungsten.

Table 1 below shows non-limiting exemplary embodiments of a polishing composition and table 2 shows non-limiting exemplary embodiments of a rinse composition. Abrasive particles of each polishing composition shown in Table 1 have a mean particle diameter of 70 nm, and are included at 1.5% by weight. Nitric acid (HNO₃) is used as the pH adjuster in each of the exemplary polishing compositions and rinse compositions. All the polishing compositions and rinse compositions use water as an aqueous carrier.

The ORP reported in tables 1 and 2 is measured via the method detailed below;

1: Prepare each sample including oxidizer. The oxidizer is added before measurement. A sample not including an oxidizer is subjected to the measurement in itself.

2: The measurement is conducted with Orion™ Versa Star Pro™ to which an ORP electrode (manufactured by Eutech Instruments Pte Ltd.; Model No. ECFG7960101B) is connected.

3: The measurement is conducted while stirring by magnetic bar (200 rpm), the sample amount is 100 g.

4: The measurement data is recorded after 1 min. The sample temperature is 25 deg. C.

TABLE 1

| | Abrasive | | Oxidizer | | Additive | | ORP |
|---|---|---|---|---|---|---|---|
| ID | Particles | Oxidizer | wt. % | Additive | wt. % | pH | (mV) |
| A | SiO₂ | n/a | n/a | n/a | n/a | 2.3 | 101 |
| B | SiO₂ | H₂O₂ | 1.00 | n/a | n/a | 2.3 | 349 |
| C | SiO₂ | KMnO₄ | 0.05 | n/a | n/a | 2.1 | 728 |
| D | SiO₂ | H₂O₂ | 1.00 | Fe(NO₃)₃ | 0.005 | 2.1 | 634 |
| E | SiO₂ with | H₂O₂ | 1.00 | n/a | n/a | 4.1 | 321 |
| | positively | | | | | | |
| | charged | | | | | | |
| | surface | | | | | | |
| F | SiO₂ with | (NH₄)₂[Ce(NO₃)₆] | 0.03 | n/a | n/a | 3.3 | 245 |
| | positively | | | | | | |
| | charged | | | | | | |
| | surface | | | | | | |
| G | ZrO₂ | KMnO₄ | 0.05 | n/a | n/a | 3.2 | 632 |
| H | ZrO₂ | Al(NO₃)₃ | 0.05 | n/a | n/a | 2.1 | 659 |

Table 1: Example polishing compositions. Abrasive particle size is 70 nm. Abrasive particle content is 1.5 wt. %. pH is adjusted by HNO₃.

Note:
SiO₂: colloidal silica
SiO₂ having positively charged surface: colloidal silica surface-modified with amino silane coupling agent. Having positive surface potential at pH in polishing.

Example polishing compositions include composition A as a control which does not include an oxidizer. Positive SiO₂ refers to SiO₂ modified to have a positive zeta potential. As shown in table 1, polishing compositions B—H span a range of ORPs from 245 up to 728.

TABLE 2

| | | | Oxidizer | | Additive | | |
|---|---|---|---|---|---|---|---|
| ID | Polymer 1/Polymer 2* | Oxidizer | wt. % | Additive | wt. % | pH | ORP |
| 1 | PSSA/PVA | n/a | n/a | n/a | n/a | 2.5 | 93 mV |
| | (0.05 wt. %/0.1 wt. %) | | | | | | |
| 2 | PSSA/PVA | H₂O₂ | 0.1 | n/a | n/a | 2.5 | 333 mV |
| | (0.05 wt. %/0.1 wt. %) | | | | | | |
| 3 | PSSA/PVA | KMnO₄ | 0.05 | n/a | n/a | 2.5 | 501 mV |
| | (0.05 wt. %/0.1 wt. %) | | | | | | |
| 4 | PSSA/PVA | H₃IO₆ | 0.05 | n/a | n/a | 2.5 | 921 mV |
| | (0.03 wt. %/0.1 wt. %) | | | | | | |
| 5 | PVA (0.1 wt. %) | n/a | 0.01 | n/a | n/a | 2.5 | 92 mV |
| 6 | PSSA/anionic PVA | n/a | n/a | n/a | n/a | 2.5 | 92 mV |
| | (0.05 wt. %/0.1 wt. %) | | | | | | |
| 7 | PSSA/PVA | n/a | n/a | n/a | n/a | 1.5 | 98 mV |
| | (0.05 wt. %/0.1 wt. %) | | | | | | |
| 8 | PSSA/PVA | n/a | n/a | n/a | n/a | 3.0 | 90 mV |
| | (0.05 wt. %/0.1. wt. %) | | | | | | |
| 9 | PSSA/PVA | n/a | n/a | n/a | n/a | 2.5 | 88 mV |
| | (0.05 wt. %/0.1 wt. %) | | | | | | |
| 10 | PSSA/PVA | H₂O₂ | 0.1 | n/a | n/a | 1.5 | 338 mV |
| | (0.05 wt. %/0.1 wt. %) | | | | | | |
| 11 | PSSA/PVA | H₂O₂ | 0.1 | n/a | n/a | 3.0 | 321 mV |
| | (0.05 wt. %/0.1 wt. %) | | | | | | |
| 12 | PSSA/PVA | H₂O₂ | 0.1 | n/a | n/a | 4.0 | 315 mV |
| | (0.03 wt. %/0.1 wt. %) | | | | | | |
| 13 | PSSA/PVA | n/a | n/a | TTHA⁵ | 0.01 | 2.5 | 95 mV |
| | (0.05 wt. %/0.1 wt. %) | | | | | | |

Table 2. Example rinse compositions. pH is adjusted by HNO₃. * All polymers have a weight average molecular weight of 10,000.

TTHA means “triethylenetetramine penta acetic acid”.

PSSA means “polystyrenesulfonic acid”.

PVA means “polyvinylalcohol”.

Anionic PVA is available from GOHSENX T-330 (Mitsubishi Chemical), and schematically has the following structure:

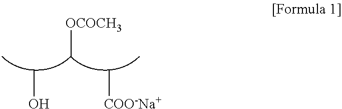

A polishing composition for a wafer may be selected based on a composition of the layer being removed. For example, abrasive particles may be selected based on a hardness of the abrasive compared to a hardness of the layer being removed. Additionally, an oxidizer of the polishing composition may be selected based on expected chemical reactions between the oxidizer and the layer being removed and/or the substrate. A rinse composition may then be chosen to balance an ORP of the polishing composition. By recognizing the balance between the rinse composition ORP (Vᵣᵢₙₛₑ) and polishing composition ORP (Vₚₒₗᵢₛₕ), a rinse composition which decreases (e.g., minimizes) defects of the wafer may be selected, without any undue experimentation on the wafer.

Table 3 below shows results for polishing and rinsing wafers, including removing layers including TEOS, tungsten, polysilicon, silicon nitride and amorphous carbon (a-carbon) separately from thermal SiO₂/Si substrate. For each test, the polishing composition is applied to a pad of a chemical mechanical polisher at a rate of 200 mL/min, the platen rotates at 60 rpm and the head holding the wafer is rotated at 65 rpm. A downward pressure of 1 psi is applied on the wafer. After polishing, the rinse composition is applied to the platen and rinsing is performed. In some examples the same platen is used for polishing and rinsing. In alternate examples the wafer is moved to a different platen for rinsing. The different rinsing platen and polishing platen may include the same type of polishing pad. In the examples of table 3, the same instrument parameters for wafer rotation, platen rotation, and solution flow rate are used for rinse as for polishing. A count of defects is given for each layer measured for each test condition. Defects size 0.1 micron or greater are counted using an automated wafer inspection device SP-1 (KLA-Tencor Corporation). “n/a” in table 3 may indicate that the test combination was not measured for the given layer. “Above measurement limit” indicates that defects are above 50,000 counts. The target of the count was the entire wafer surface (300 mm) (excluding 5 mm of the peripheral).

Conditions of polishing and rinsing tests as documented in table 3 are provided below;
Polishing machine: Applied Materials Inc., Reflexion® LK CMP;
Pad: Fujibo Holdings Inc., Polypas™ H800;
Conditioning agent: 3M™ CMP pad conditioner brush;
Down force: 1 psi;
Platen rotation: 60 rpm;
Head rotation: 65 rpm
Composition flow rate: 200 mL/min;
Polishing time: 60 sec.
The pad is of polyurethane.

Detailed composition of wafers used in the tests documented in Table 3 are provided below; Composition of wafers is listed in order from bottom to top.
TEOS; Advantiv Technologies, Inc.
Si substrate/thermal oxide/PE-TEOS 10000 angstrom
Poly-Si; Advantiv Technologies, Inc.
Si substrate/thermal oxide/Poly-Si 8000 angstrom
SiN: Advanced Materials Technology, Inc.
Si substrate/thermal oxide/LP-SiN 3500 angstrom
Amorphous carbon; DK Nanotechnology, Inc.
Si substrate/thermal oxide/a-carbon
W; Advanced Materials Technology, Inc.
Si substrate/thermal oxide/TiN 100 angstrom/PVD-W 8000 angstrom.

One aspect of the present invention provides a kit of a composition for chemical mechanical planarization of a wafer, comprising a polishing composition for polishing the wafer comprising abrasive particles, a pH adjuster, and an oxidizer; and a rinse composition, to be used in a rinse step performed after a polishing step, for rinsing the wafer comprising at least one anionic polymer and a pH adjuster, wherein a ratio of an oxidation-reduction potential of the rinse composition to an oxidation-reduction potential of the polishing composition is greater than 0 and less than 0.76. The descriptions of the system and the method given herein are similarly applied as the description of such a kit.

TABLE 3

| | Polishing | Rinse | | | | | | |
|---|---|---|---|---|---|---|---|---|
| | Composition | Composition | Vᵣᵢₙₛₑ/ | Defect Counts | | | | |
| No. | (Oxidizer) | (Oxidizer) | Vₚₒₗᵢₛₕ | TEOS | poly-Si | SiN | -a-carbon | W |
| 1 | A | — | — | 4361 | Above | Above | n/a | 2111 |
| | Not use | | | | measurement | measurement | | |
| | | | | | limit | limit | | |
| 2 | B | — | — | 2434 | Above | Above | n/a | 1999 |
| | H₂O₂ | | | | measurement | measurement | | |
| | | | | | limit | limit | | |
| 3 | B | 5 | 0.26 | 321 | 1031 | Above | n/a | 371 |
| | H₂O₂ | Not use | | | | measurement | | |
| | | | | | | limit | | |
| 4 | B | 1 | 0.27 | 311 | 1029 | 299 | n/a | 333 |
| | H₂O₂ | Not use | | | | | | |
| 5 | B | 6 | 0.26 | 310 | 1033 | 298 | n/a | 342 |
| | H₂O₂ | Not use | | | | | | |
| 6 | B | 4 | 2.64 | 1201 | 3356 | 449 | n/a | 764 |
| | H₂O₂ | H₅IO₆ | | | | | | |
| 7 | B | 7 | 0.28 | 312 | 1030 | 286 | n/a | 334 |
| | H₂O₂ | Not use | | | | | | |
| 8 | B | 8 | 0.26 | 314 | 1034 | 301 | n/a | 333 |
| | H₂O₂ | Not use | | | | | | |
| 9 | B | 9 | 0.25 | 312 | 1033 | 309 | n/a | 336 |
| | H₂O₂ | Not use | | | | | | |
| 10 | B | 13 | 0.27 | 311 | 1031 | 299 | n/a | 321 |
| | H₂O₂ | Not use | | | | | | |
| 11 | C | — | — | Above | Above | Above | Above | n/a |
| | KMnO₄ | | | measurement | measurement | measurement | measurement | |
| | | | | limit | limit | limit | limit | |
| 12 | C | 2 | 0.46 | 234 | 1431 | 257 | 921 | n/a |
| | KMnO₄ | H₂O₂ | | | | | | |
| 13 | C | 4 | 1.27 | Above | Above | Above | Above | n/a |
| | KMnO₄ | H₅IO₆ | | measurement | measurement | measurement | measurement | |
| | | | | limit | limit | limit | limit | |
| 14 | D | — | — | 3891 | 4461 | 1027 | 1111 | n/a |
| | H₂O₂ | | | | | | | |
| 15 | D | 2 | 0.53 | 811 | 1219 | 489 | 472 | 472 |
| | H₂O₂ | H₂O₂ | | | | | | |
| 16 | D | 4 | 1.45 | 6341 | 3469 | 1980 | Above | 2341 |
| | H₂O₂ | H₅IO₆ | | | | | measurement | |
| | | | | | | | limit | |
| 17 | E | — | — | 4321 | 4231 | 2984 | n/a | 2398 |
| | H₂O₂ | | | | | | | |
| 18 | E | 2 | 1.04 | 1781 | 1200 | 1384 | n/a | 1289 |
| | H₂O₂ | H₂O₂ | | | | | | |
| 19 | F | — | — | 2341 | 3201 | 2289 | 5673 | 791 |
| | (NH₄)₂ | | | | | | | |
| | [Ce(NO₃)₆] | | | | | | | |
| 20 | F | 1 | 0.38 | 521 | 1030 | 666 | 791 | 341 |
| | (NH₄)₂[Ce(NO₃)₆] | Not use | | | | | | |
| 21 | F | 2 | 1.36 | 1218 | 2145 | 931 | 2119 | 561 |
| | (NH₄)₂ | H₂O₂ | | | | | | |
| | [Ce(NO₃)₆] | | | | | | | |
| 22 | G | — | — | Above | n/a | 4121 | Above | 2111 |
| | KMnO₄ | | | measurement | | | measurement | |
| | | | | limit | | | limit | |
| 23 | G | 1 | 0.15 | 281 | n/a | 500 | 1203 | 451 |
| | KMnO₄ | Not use | | | | | | |
| 24 | G | 2 | 0.53 | 111 | n/a | 154 | 991 | 342 |
| | KMnO₄ | H₂O₂ | | | | | | |
| 25 | G | 10 | 0.53 | 112 | n/a | 121 | 992 | 333 |
| | KMnO₄ | H₂O₂ | | | | | | |
| 25 | G | 11 | 0.51 | 110 | n/a | 155 | 995 | 341 |
| | KMnO₄ | H₂O₂ | | | | | | |
| 26 | G | 12 | 0.50 | 110 | n/a | 160 | 990 | 345 |
| | KMnO₄ | H₂O₂ | | | | | | |
| 27 | G | 3 | 0.79 | 2451 | n/a | 4421 | Above | n/a |
| | KMnO₄ | KMnO₄ | | | | | measurement | |
| | | | | | | | limit | |
| 28 | H | 1 | 0.14 | 515 | 401 | 552 | n/a | 300 |
| | Al(NO₃)₃ | Not use | | | | | | |
| 29 | H | 2 | 0.51 | 346 | 304 | 299 | n/a | 342 |
| | Al(NO₃)₃ | H₂O₂ | | | | | | |
| 30 | H | 3 | 0.76 | 776 | 1262 | 854 | n/a | 1734 |
| | Al(NO₃)₃ | KMnO₄ | | | | | | |

Table 3. Defect counts of different types of layers when polished and cleaned using the exemplary polishing compositions and rinse compositions of tables 1 and 2.

As described above, when the combination of a polishing composition comprising abrasive particles, a pH adjuster, and an oxidizer, and a rinse composition comprising an anionic polymer and a pH adjuster, having a ratio of an oxidation-reduction potential of the rinse composition to an oxidation-reduction potential of the polishing composition of greater than 0 and less than 0.76 is employed, the “Defect Counts” can be generally decreased.

Since an example No. 3 does not comprise an anionic polymer in the rinse composition, the count of defects in SiN is above the measurement limit.

Since Vᵣᵢₙₛₑ/Vₚₒₗᵢₛₕ is 0.76 or greater in an example No. 6, the count of defects in polysilicon is as large as 3356.

Since no rinse composition is used in an example No. 14, the count of defects in TEOS is as large as 3891, and the count of defects in polysilicon is as large as 4461.

Since Vᵣᵢₙₛₑ/Vₚₒₗᵢₛₕ is 0.76 or greater in an example No. 18, the count of defects in TEOS is as large as 1781.

Since Vᵣᵢₙₛₑ/Vₚₒₗᵢₛₕ is 0.76 or greater in an example No. 21, the count of defects in polysilicon is as large as 2145.

Since Vᵣᵢₙₛₑ/Vₚₒₗᵢₛₕ is 0.76 or greater in an example No. 30, the count of defects in W is as large as 1734.

In some examples, “Defect Counts” of over 1500 in at least one of TEOS, poly-Si, SiN, a-carbon, and W is unpreferable.

In some examples, “Defect Counts” of over 1500 in at least one of TEOS, poly-Si, SiN, and W is unpreferable.

In some examples, “Defect Counts” of over 1500 in at least one of TEOS, poly-Si, SiN, and W is unpreferable.

In some examples, “Defect Counts” of over 1500 in at least one of TEOS, SiN, and W is unpreferable.

The results shown in table 3 illustrate the decrease in number of defects that is achieved when the ORP of the rinse composition is balanced with the ORP of the polishing solution. Comparing defects counted after polishing with polishing composition A which does not include an oxidant to polishing composition B which includes an oxidant, a number of defects in some layers decreases with addition of the oxidant. Comparing defects of layers that were polished with polishing composition without a rinse composition to the same polishing composition with a rinse composition, a number of defects also decreases when a rinse composition is applied. Across all polishing compositions, a number of defects decreases when the ORP of the rinse composition is balanced to the ORP of the polishing to put the ratio of Vᵣᵢₙₛₑ/Vₚₒₗᵢₛₕ within the range as described above. The balanced rinse composition may be different depending on properties of the corresponding polishing composition. For example, the smallest number of defects for polishing composition B are counted when rinse composition 1 is used whereas the smallest number of defects for polishing composition C are counted when rinse composition 2 is used. A total number of defects may also decrease when Vᵣᵢₙₛₑ/Vₚₒₗᵢₛₕ is at a lower end of the range of greater than zero to less than 0.76. For example, a number of defects for TEOS, a-carbon, and W layers decreases compared to a control with no rinse composition when a combination of polish composition G and rinse composition 1 are used resulting in a Vᵣᵢₙₛₑ/Vₚₒₗᵢₛₕ ratio of 0.15.

The technical effect of methods 100 and 300 is to decrease (e.g., minimize) a number of defects in a wafer after CMP. The balanced rinse composition may be selected and prepared without undue experimentation on the wafer by ensuring a ratio of ORP of the rinse composition of ORP of the polishing composition is within a range. The balanced polishing and rinse compositions may result in oxidizing defect causing material to an extent that the defect causing material is the most hydrophilic and therefore most likely to be removed by aqueous rinsing and cleaning compositions. Minimizing a number of defects in the wafer may help to maximize a number of successful nano/microelectronic devices produced from a wafer.

The disclosure also provides support for a system for chemical mechanical planarization of a wafer, comprising: a polishing composition for polishing the wafer comprising abrasive particles, a pH adjuster, and an oxidizer; and a rinse composition for rinsing the wafer comprising at least one polymer and a pH adjuster, wherein a ratio of an oxidation-reduction potential of the rinse composition to an oxidation-reduction potential of the polishing composition is greater than 0 and less than 0.76. In a first example of the system, the at least one polymer includes polystyrenesulfonic acid or copolymers of styrene sulfonic acid and polyvinylalcohol or copolymers of polyvinylalcohol, and wherein a degree of saponification of the at least one polymer is not 100%. In a second example of the system, optionally including the first example, the rinse composition includes an oxidizer. In a third example of the system, optionally including one or both of the first and second examples, the rinse composition includes hydrogen peroxide. In a fourth example of the system, optionally including one or more or each of the first through third examples, a Mohs hardness of the abrasive is less than 9. In a fifth example of the system, optionally including one or more or each of the first through fourth examples, a Mohs hardness of the abrasive is more than 7. In a sixth example of the system, optionally including one or more or each of the first through fifth examples, the abrasive particles are ZrO₂ or SiO₂.

The disclosure also provides support for a method for chemical mechanical planarization, comprising: contacting a surface of a wafer with polishing composition having an oxidation-reduction potential while polishing a surface of the wafer, the polishing composition comprising abrasive particles, a pH adjuster, and an oxidizer; and contacting the polished surface of the wafer with a rinse composition and rinse the wafer, the rinse composition comprising at least one polymer and a pH adjuster, and a positive oxidation-reduction potential at least 1.5 times less than the oxidation-reduction potential of the polishing composition. In a first example of the method, the oxidizer is hydrogen peroxide and the rinse composition does not include an oxidizer. In a second example of the method, optionally including the first example, the oxidizer is potassium permanganate and the rinse composition includes an oxidizer comprised of hydrogen peroxide. In a third example of the method, optionally including one or both of the first and second examples, contacting the polished surface with the rinse composition includes feeding the rinse composition onto a platen of a chemical mechanical planarization system. In a fourth example of the method, optionally including one or more or each of the first through third examples, the surface of the polishing object includes a layer formed of one of: TEOS, polycrystalline silicon, silicon nitride, amorphous carbon, or tungsten. In a fifth example of the method, optionally including one or more or each of the first through fourth examples, the abrasive particles are one of SiO₂ or ZrO₂.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements.

Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

### REFERENCE SIGNS LIST

100 method for polishing and rinsing wafer
200 CMP system
202 platen
204 polishing pad
206 wafer holder
208 supply system
210 composition
212 rotational axis
214 axis
300 method

What is claimed is:

1. A system for chemical mechanical planarization of a wafer, comprising:
a polishing composition for polishing the wafer comprising abrasive particles, a pH adjuster, and an oxidizer; and
a rinse composition, to be used in a rinse step performed after a polishing step, for rinsing the wafer comprising at least one anionic polymer and a pH adjuster,
wherein a ratio of an oxidation-reduction potential of the rinse composition to an oxidation-reduction potential of the polishing composition is greater than 0 and less than 0.76.

2. The system of claim 1, wherein the ratio of the oxidation-reduction potential of the rinse composition to the oxidation-reduction potential of the polishing composition is less than 0.65.

3. The system of claim 1, wherein the anionic polymer comprises a sulfonic acid group.

4. The system of claim 3, wherein the anionic polymer comprises at least one of polystyrenesulfonic acid and a copolymer of styrene sulfonic acid and polyvinylalcohol.

5. The system of claim 1, wherein the rinse composition comprises a nonionic polymer.

6. The system of claim 5, wherein the nonionic polymer comprises polyvinylalcohol, and wherein a degree of saponification of the polyvinylalcohol is not 100%.

7. The system of claim 1, wherein a Vickers hardness of the abrasive particles is less than 11.

8. The system of claim 1, wherein a Vickers hardness of the abrasive particles is 11 or greater.

9. The system of claim 7, wherein the abrasive particles are SiO₂.

10. The system of claim 8, wherein the abrasive particles are ZrO₂.

11. The system of claim 1, wherein when a Vickers hardness of the abrasive particles is less than 11, the ratio of the oxidation-reduction potential of the rinse composition to the oxidation-reduction potential of the polishing composition is greater than 0 and less than 0.38.

12. The system of claim 1, wherein when a Vickers hardness of the abrasive particles is 11 or greater, the ratio of the oxidation-reduction potential of the rinse composition to the oxidation-reduction potential of the polishing composition is greater than 0.14.

13. The system of claim 1, wherein the ratio of the oxidation-reduction potential of the rinse composition to the oxidation-reduction potential of the polishing composition is greater than 0.15.

14. The system of claim 1, wherein when a Vickers hardness of the abrasive particles is 11 or greater, the polishing composition comprises potassium permanganate.

15. A rinse composition to be used in a rinse step performed after a polishing step using a polishing composition for polishing a wafer comprising abrasive particles, a pH adjuster, and an oxidizer, wherein a ratio of an oxidation-reduction potential of the rinse composition to an oxidation-reduction potential of the polishing composition is greater than 0 and less than 0.76.

16. A method for chemical mechanical planarization of a wafer, comprising:
a polishing step of contacting a surface of the wafer with a polishing composition for polishing the wafer comprising abrasive particles, a pH adjuster, and an oxidizer; and
a rinse step of contacting the polished surface of the wafer after the polishing step with a rinse composition for rinsing the wafer comprising at least one anionic polymer and a pH adjuster,
wherein a ratio of an oxidation-reduction potential of the rinse composition to an oxidation-reduction potential of the polishing composition is greater than 0 and less than 0.76.

17. The method of claim 16, wherein the surface of the wafer includes a layer formed of at least one of: TEOS, polycrystalline silicon, silicon nitride, amorphous carbon, or tungsten.
